(19) United States
(12) Patent Application Publication
(10) Pub. No.: US 2008/0062361 A1
(43) Pub. Date: Mar. 13, 2008

(54) DISPLAY PANEL AND METHOD FOR MANUFACTURING A COLOR FILTER SUBSTRATE OF THE DISPLAY PANEL

(75) Inventors: Sung-Jin Jang, Daejeon (KR); Sang-Woo Park, Seoul (KR); Do-Hoon Kim, Guri-si (KR); Min-Chang Kim, Goyang-si (KR); Jin-Yup Kim, Asan-si (KR); Ji-Eun Lee, Seoul (KR); Dong-Yoon So, Seoul (KR)

Correspondence Address: MACPHERSON KWOK CHEN & HEID LLP, 2033 GATEWAY PLACE, SUITE 400, SAN JOSE, CA, 95110, US

(73) Assignee: SAMSUNG ELECTRONICS CO., LTD., Suwon-Si (KR)

(21) Appl. No.: 11/853,462

(22) Filed: Sep. 11, 2007

(30) Foreign Application Priority Data
Sep. 11, 2006 (KR) 2006-87145

(51) Int. Cl. G02F 1/1335; H01L 21/02

(52) U.S. Cl. 349/106; 438/30; 257/E21.536

(57) ABSTRACT

A display panel includes an array substrate and a color filter substrate. The array substrate has a transparent electrode formed in a pixel area of a base substrate, and a reflective electrode formed on the transparent electrode and in a reflective area of the pixel area. The color filter substrate is combined with the array substrate, and includes a light-blocking pattern defining the pixel area, a photo pattern formed in the reflective area and a color filter formed on the photo pattern of the reflective area and in a transmissive area of the pixel area. Brightness and color reproducibility in the reflective area are adjusted to correspond to those in the transmissive area, and may be easily controlled without additional masks, so that display quality is enhanced and the display substrate is easily manufactured, thereby reducing manufacturing costs and enhancing display productivity.

### RELATED APPLICATIONS

This application claims priority of Korean Patent Application No. 2006-87145, filed Sep. 11, 2006, the entire disclosure of which is incorporated herein by reference.

### BACKGROUND

This disclosure relates to display panels, such as liquid crystal display (LCD) panels, and to methods for manufacturing color filter substrates for such panels. More particularly, the disclosure relates to display panels having an enhanced display quality and manufacturing productivity, and to methods for manufacturing color filter substrates for such panels.

An LCD apparatus typically includes a display panel having an array substrate with a plurality of switching elements thereon, a color filter substrate disposed opposite to the array substrate and having a plurality of color filters thereon, and a layer of a liquid crystal material disposed between the array and the color filter substrates. The display panel receives light from a backlight assembly disposed behind the display panel, and applies an electric field to the liquid crystal layer to change the arrangement of the liquid crystal molecules of the liquid crystal layer such that an image is displayed on the panel.

The display panel may be classified as a reflective type display panel, a transmissive type display panel or a transflective type display panel, depending on the source of light used to form the image. Reflective type display panels reflect external light provided from the exterior of the panel to display an image. Transmissive type display panels transmit light incident on a back surface of the display panel to display an image. As mentioned above, the incident light of a transmissive type display panel is typically generated by a backlight assembly disposed behind the panel. Transflective type display panels both reflect external incident light and transmit light incident from a backlight to display an image.

In the color filters of the transflective type of display panels, a light hole is formed at the color filter corresponding to a reflective area, so that the brightness and color reproducibility in the reflective area may be adjusted so as to have substantially the same brightness and color reproducibility as in the adjacent transmissive area of the color filter. Additionally, the size of the light hole may be changed during manufacturing to control the brightness and the color reproducibility in the reflective area. However, in order to control the size of the light holes accurately, it is necessary to have a number of masks with different designs, the provision and use of which may increase manufacturing costs.

### BRIEF SUMMARY

In accordance with the exemplary embodiments disclosed herein, methods are provided for manufacturing color filter substrates of LCD display panels that result in panels with enhanced display quality and manufacturing productivity.

In one exemplary embodiment, a display panel includes an array substrate and a counter substrate. The array substrate has a transparent electrode formed in a pixel area of a base substrate, and a reflective electrode formed on the transparent electrode and in a reflective area of the pixel area. The counter substrate is combined with the array substrate, with a liquid crystal layer disposed therebetween, and includes a light-blocking pattern defining the pixel area, a photo pattern formed in the reflective area and a color filter formed on the photo pattern of the reflective area and in a transmissive area of the pixel area.

An exemplary embodiment of a method for manufacturing a display substrate includes forming a light-blocking pattern defining a pixel area of a base substrate, forming a photo pattern in a reflective area of the pixel area, and forming a color filter on the photo pattern and in a transmissive area of the pixel area.

In accordance with the exemplary embodiments disclosed herein, the brightness and color reproducibility in the reflective areas of the pixel areas is adjusted to correspond to those in the transmissive areas thereof and is easily controlled without the need for additional masks, so that display quality is thereby enhanced, manufacturing costs and processes are simplified, and manufacturing productivity is enhanced.

A better understanding of the above and many other features and advantages of the novel display panel substrates of the present invention and the methods by which they are made may be obtained from a consideration of the detailed description of some exemplary embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a partial plan view of an exemplary embodiment of an LCD display panel in accordance with the present invention;

FIG. 2 is a partial cross-sectional view of the exemplary display panel of FIG. 1, as seen along the lines of the section I-I′ taken therein;

FIG. 3 is a partial cross-sectional view another exemplary embodiment of an LCD display substrate in accordance with the present invention;

FIGS. 4A to 5B are partial cross-sectional views of alternative exemplary embodiments of color filter substrates for LCD display panels in accordance with the present invention;

FIG. 6A to 6D are partial cross-sectional views illustrating sequential processes of an exemplary embodiment of a method for manufacturing a color filter substrate of an LCD in accordance with the present invention; and,

FIGS. 7A and 7B are partial cross-sectional views illustrating sequential processes of another exemplary embodiment of a method for manufacturing an LCD color filter substrate in accordance with the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

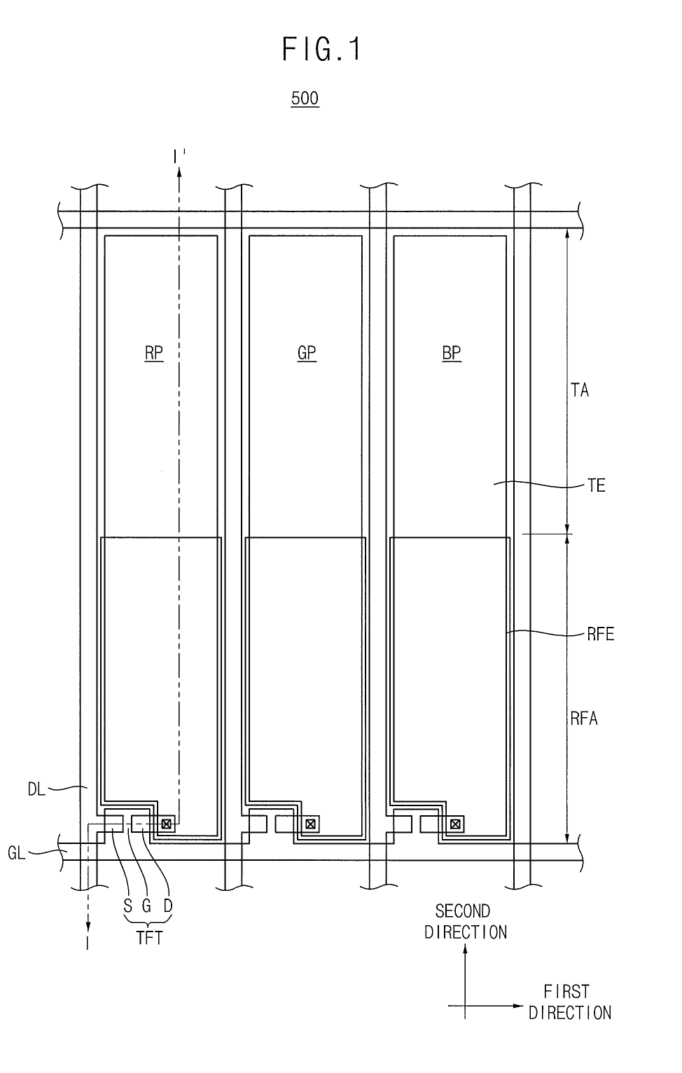

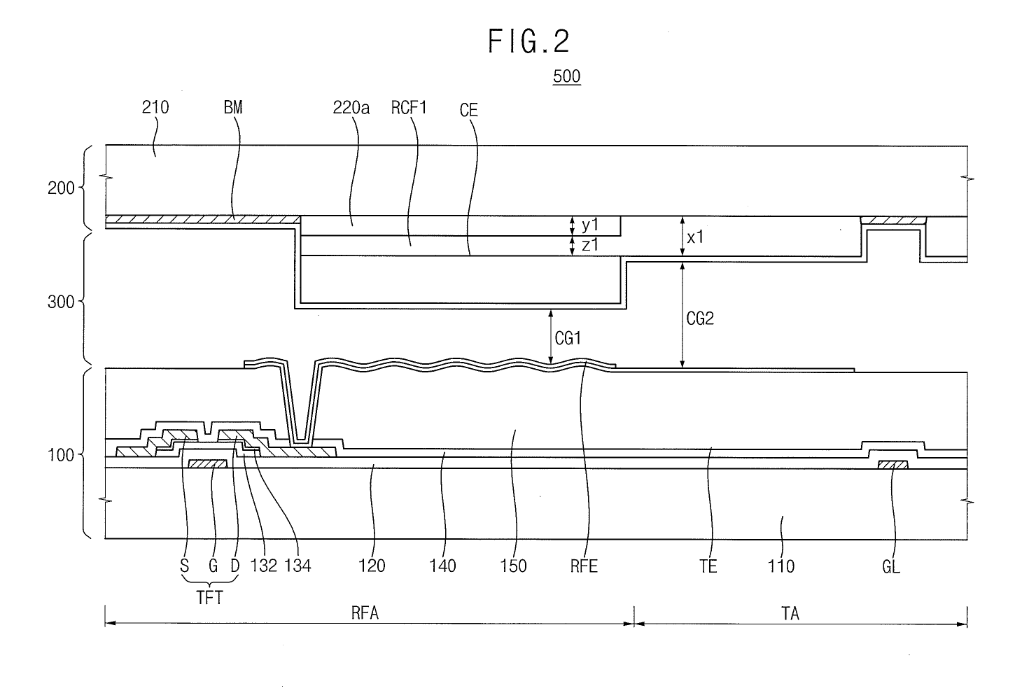

FIG. 1 is a partial plan view of an exemplary embodiment of an LCD display panel in accordance with the present invention, and FIG. 2 is a partial cross-sectional view of the exemplary display panel of FIG. 1, as seen along the lines of the section I-I′ taken therein. As illustrated in FIGS. 1 and 2, the first exemplary display panel 500 includes a first array substrate 100, a first color filter substrate disposed opposite to the first array substrate 100, and a liquid crystal layer 300 disposed between the first array substrate 100 and the first color filter substrate 200.

The first exemplary array substrate 100 has gate lines GL extending along a first direction, as indicated by the set of coordinate axes of FIG. 1, source lines DL extending along a second direction substantially perpendicular to the first direction so as to cross the gate lines GL, and a switching element TFT electrically connected to each gate line GL and associated source line DL that are formed on the base substrate 110. The gate lines GL and the source lines DL thus cross each other to define a plurality of pixel areas RP, GP and BP on the first base substrate 110. Each pixel area RP, GP and BP is divided into a transmissive area TA that transmits external light and a reflective area RFA that reflects external light.

The switching element TFT includes a gate electrode G electrically connected to the gate line GL, a source electrode S electrically connected to the source line DL and a drain electrode D that is separate from the source electrode S. A portion of the drain electrode D makes contact with a pixel electrode TE and RFE, so that the switching element TFT is electrically connected to the pixel electrode TE and RFE.

As illustrated in FIG. 2, a gate insulating layer 120 is formed on the first base substrate 110 on which the gate lines GL and the gate electrode G are formed. A semiconductor layer 132 and an ohmic contact layer 134 are formed on the gate insulating layer 120 in an area corresponding to the gate electrode G.

A passivation layer 140 is formed on the first base substrate 110 on which the gate lines GL, the source lines DL and the switching elements are formed. A first organic layer 150 is formed on the passivation layer 140 in the reflective area RFA. The first organic layer 150 acts to flatten the upper surface of the first array substrate 100, so that the height differences in the stepped portions of the layers formed in the reflective area RFA and the transmissive area TA are minimized. The first organic layer 150 may have a concavo-convex pattern formed thereon to enhance the reflective ratio in the reflective area RFA.

The pixel electrode TE and RFE formed on the first organic layer 150 includes a transparent electrode TE formed in the reflective area RFA and the transmissive area TA, and a reflective electrode RFE formed on the transparent electrode TE in the reflective area RFA. The transparent electrode TE comprises a transparent conductive material, for example, indium tin oxide (ITO) or indium zinc oxide (IZO). The reflective electrode RFE includes a metal having a good reflective ratio, such as silver (Ag) and silver-molybdenum (Ag—Mo: AMO).

The first exemplary color filter substrate 200 includes a light-blocking pattern BM defining pixel areas RP, GP and BP corresponding to those of the first array substrate 100, first photo patterns, including a first photo pattern 220a formed in a red pixel area RP, and color filters of different colors, including a red color filter RCF formed in the red color filter area RP. The structure of each pixel area RP, GP and BP of the first color filter substrate 200 is the same as that of the red pixel area RP of the first color filter substrate 200 in FIGS. 1 and 2, except for the color of the associated color filter. Thus, the red pixel area RP of the first color filter substrate 200 is described below by way of example and with reference to FIGS. 1 and 2.

The light-blocking pattern BM divides a second base substrate 210 into the plurality of pixel areas RP, GP and BP. The shape of the light-blocking pattern BM generally corresponds to that of the gate lines GL, the source lines DL and the switching element TFT of the first array substrate 100. The light-blocking pattern BM functions to enhance the contrast ratio of the first exemplary display panel 500 and also blocks external light flowing into the switching element TFT, thereby preventing the generation of an undesirable leakage current therein. The light-blocking pattern BM is formed via patterning a black matrix layer comprising a metal or an organic material.

The color filters are formed in each pixel area RP, GP and BP defined by the light-blocking pattern BM. The color filters include a red color filter formed in each of the red pixel areas RP, a green color filter formed in each of the green pixel areas GP and a blue color filter formed in each of the blue pixel areas BP. The red, green and blue color filters are arrayed in repetitive patterns so as to enable the display panel 500 to display a multitude of colors.

The first photo pattern 220a formed in the red pixel area RP is formed in the reflective area RFA of the red pixel area RP. The first photo pattern 220a includes a photosensitive organic material. For example, the photosensitive organic material may comprise a negative type photoresist composite material, a portion of which is cured by irradiation with light, and the portion of which that is not irradiated by light being eliminated by a developer. Alternatively, the photosensitive organic material may include a positive type photoresist composite material, a portion of which that is irradiated by the light being eliminated by the developer and the portion of which that is not irradiated by the light being cured. The first photo pattern 220a formed in the red pixel area RP functions to adjust the transmissive ratio and color reproducibility of the red color filter RCF formed on the first photo pattern 220a to be substantially the same as those of the red color filter RCF formed in the transmissive area TA of the red pixel area RP, so that the brightness and color reproducibility in the red pixel area RP are thereby optimized.

The red color filter RCF is formed to make contact with the first photo pattern 220a in the reflective area RFA of the red pixel area RP of the transmissive area TA of the second base substrate 210. As illustrated in FIG. 2, a first thickness xl of the red color filter RCF is defined as the height from the surface of the second base substrate 210 to the lower surface of the red color filter RCF, and a second thickness yl of the first photo pattern 220a is defined as the height from the surface of the second base substrate 210 to the lower surface of the first photo pattern 220a. That is, the portion of the red color filter RCF disposed in the transmissive area TA has a first thickness x1, whereas, the portion of the red color filter RCF disposed in the reflective area RFA has a third thickness z1 that is equal to the difference between the first thickness x1 and the second thickness y1 due to the presence of the first photo pattern 220a therein.

Thus, the thickness z1 of the red color filter RCF in the reflective are RFA of the red pixel area RP is less than the thickness x1 of the red color filter RCF in the transmissive area TA thereof by an amount that is equal to the thickness y1 of the first photo pattern 220a in the red pixel area RP. Accordingly, the color reproducibility of the red color filter RCF formed in the reflective area RFA is somewhat decreased, but the transmissivity of the red color filter RCF formed in the reflective area RFA is enhanced, so that the brightness in the red pixel area RP is thereby enhanced. As a result, the difference between the brightness and color reproducibility in the reflective area RFA and those in the transmissive area TA may be minimized so as to enhance display quality of the first display panel 500.

A second organic layer 230 is formed on the red color filter RCF in the reflective area RFA corresponding to the first photo pattern 220a. The second organic layer 230 functions to change the size of the cell gap CG of the first liquid crystal layer 300 in the region of the first photo pattern 220a so as to adjust the phase difference of the light in a transflective liquid crystal display panel having a transmissive area TA and a reflective area RFA in the red pixel area RP. Thus, as illustrated in FIG. 2, the first cell gap CG1 of the liquid crystal layer 300 in the reflective area RFA is smaller than the second cell gate CG2 of the liquid crystal layer 300 in the transmissive area TA. For example, the second cell gap CG2 may be twice as large as the first cell gap GC1. In one possible exemplary embodiment, the second organic layer 230 may comprise an acrylic resin.

In the exemplary embodiment of FIG. 2, only the red pixel area, including the red color filter, is illustrated and described by way of example, but it should be understood that another first photo pattern (not illustrated) may be formed in the reflective area RFA of the green pixel area GP, together with a green color filter formed thereon, and yet another first photo pattern (not illustrated) may be formed in the reflective area RFA of the blue pixel area BP, together with a blue color filter formed thereon, in a manner substantially similar to that described above in connection with the red pixel area.

The first photo patterns, including the first photo pattern 220, are formed in the first exemplary display panel 500, and the color filters are formed on the first photo patterns, so that the transmissivity and color reproducibility of the color filters formed in each reflective area RFA may be adjusted to be similar to those of the color filters formed in each adjacent transmissive area TA. Accordingly, the brightness and the color reproducibility of each pixel area RP, GP and BP in the first exemplary LCD display panel 500 are thereby optimized, so that the display quality of the first exemplary display panel 500 is thereby enhanced.

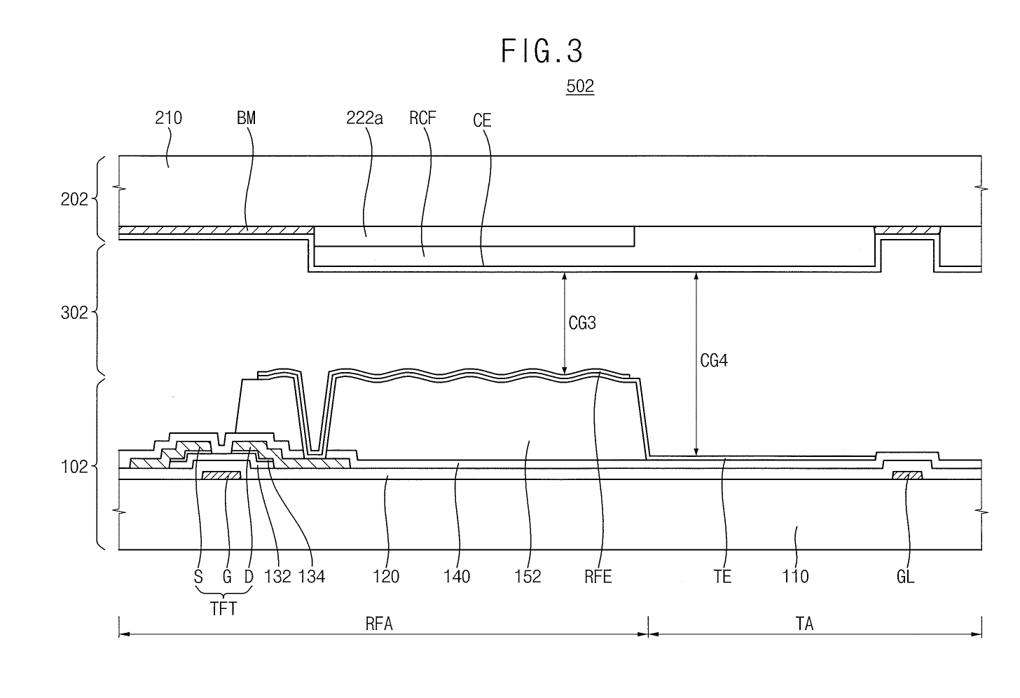

FIG. 3 is a partial cross-sectional view another exemplary embodiment of an LCD display substrate 502 in accordance with the present invention. As in the first exemplary embodiment of panel 500 discussed above, only the red pixel area of the second display panel is described below by way of example of the other pixel areas, and further detailed description of the elements that are the same or substantially similar to those of the first display panel is omitted for brevity.

Referring to FIG. 3, the second display panel 502 includes a second array substrate 102, a second color filter substrate 202 disposed opposite to the second array substrate 102, and a second liquid crystal layer 302 disposed between the second array substrate 102 and the second color filter substrate 202.

The second array substrate 102 includes a gate line GL and a source line (not seen in FIG. 3) defining pixel areas, a switching element TFT, a passivation layer 140 formed on the source lines and the switching element TFT, a third organic layer 152 formed on the passivation layer 140, and a pixel electrode TE and RFE formed on the third organic layer 152. The pixel area is divided into a reflective area RFA and a transmissive area TA.

The third organic layer 152 is formed in the reflective area RFA. As above, the third organic layer 152 functions to adjust the phase difference of external light respectively passing through the reflective area RFA and the transmissive area TA in a transflective mode of display. The third organic layer 152 may include a concavo-convex pattern on its upper surface to enhance the reflective ratio in the reflective area RFA.

The pixel electrode TE and RFE includes a transparent electrode TE formed in both the reflective area RFA and the transmissive area TA of the second array substrate 102, and a reflective electrode RFE formed on the transparent electrode TE and the third organic layer 152 in the reflective area RFA.

As discussed above, the third organic layer 152 of the second array substrate 202 functions to adjust the phase difference of the external light respectively passing through the transmissive area TA and the reflective area RFA of the second display panel 502 by adjusting the thickness of the respective cell gaps therein. Thus, the third organic layer 152 makes a third cell gap CG3 of the second liquid crystal layer 302 in the reflective area RFA thinner than a fourth cell gap CG4 of the second liquid crystal layer 302 in the transmissive area TA.

In FIG. 3, the second color filter substrate 202 includes a light-blocking pattern BM formed on the second base substrate 210, a second photo pattern 222a formed in the reflective area RFA, a red color filter RCF, and a common electrode layer CE formed on the second base substrate 210. An organic layer (not illustrated) that minimizes the unevenness of the stepped portion of the light-blocking pattern BM and the red color filter RCF may be formed under the common electrode layer CE.

The second photo pattern 222a is formed in the reflective area RFA, and the red color filter RCF is formed on the second photo pattern 222a and the second base substrate 210. The thickness of the red color filter RCF formed in the reflective area RFA over the second photo pattern 222a is thinner than that of the red color filter RCF formed in the transmissive area TA. As a result, the color reproducibility of the red color filter RCF in the reflective area RFA is decreased somewhat, but the transmissivity of the red color filter RCF in the reflective area RFA is enhanced, so that the brightness and the color reproducibility in the reflective area RFA may be easily adjusted to match those in the transmissive area TA. Accordingly, the brightness and color reproducibility in the red pixel area may be completely optimized so as to enhance the display quality. As above, the red pixel area has been described in detail by way of example, but it should be understood that the brightness and color reproducibility in the respective reflective and transmissive areas of the green and blue pixel areas adjacent to the red pixel area may be optimized in a similar manner.

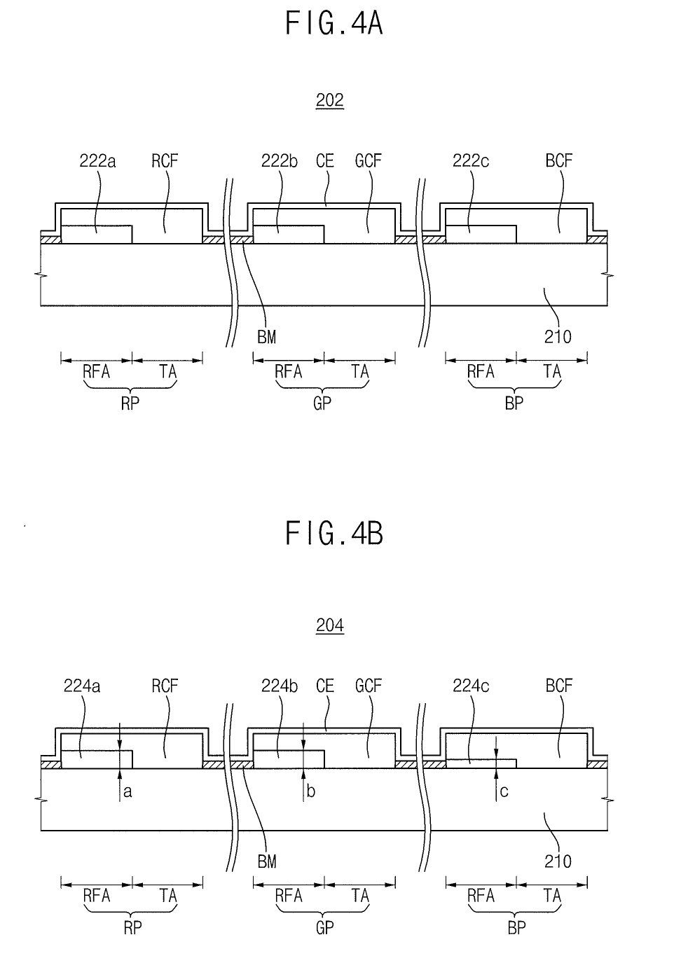

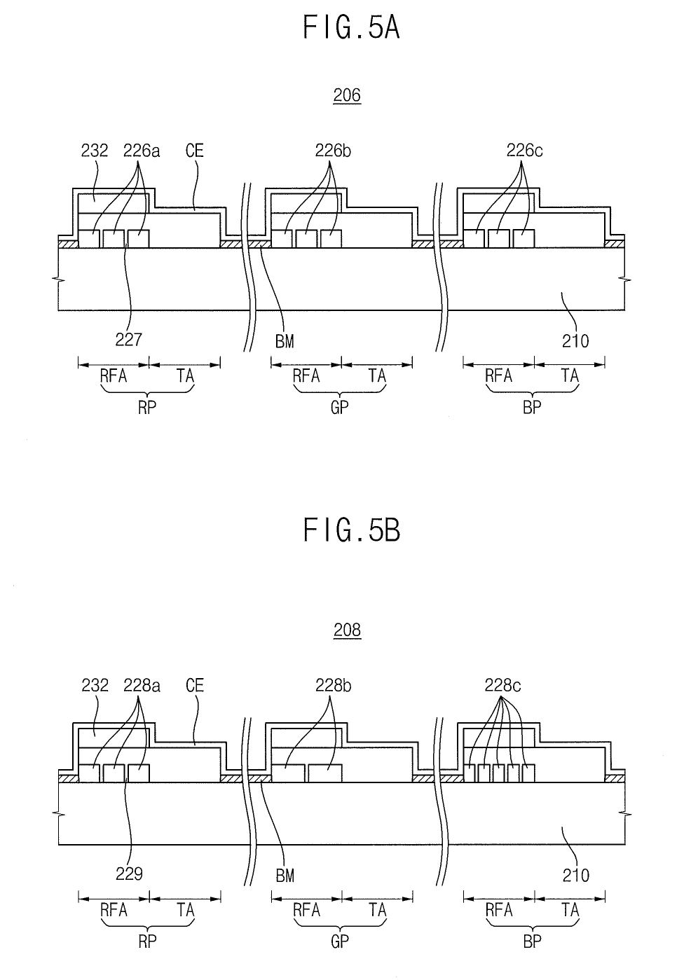

FIGS. 4A to 5B are partial cross-sectional views of alternative exemplary embodiments of color filter substrates for LCD display panels in accordance with the present invention.

Referring to FIGS. 3 and 4A, second photo patterns 222a, 222b and 222c, color filters RCF, GCF and BCF formed on the second photo patterns 222a, 222b and 222c, and a common electrode layer CE formed on the light-blocking pattern BM and the color filters RCF, GCF and BCF are formed in each pixel area RP, GP and BP defined by the light-blocking pattern BM of the second color filter substrate 202.

For example, the first one 222a of the second photo patterns 222a, 222b and 222c is formed in the reflective area RFA of the red pixel area RP, and the red color filter RCF is formed on the first one 222a of the second photo patterns 222a, 222b and 222c and the second base substrate 220 in the transmissive area TA of the red pixel area RP. The second one 222b of the second photo patterns 222a, 222b and 222c is formed in the reflective area RFA of the green pixel area GP adjacent to the red pixel area RP. The third one 222c of the second photo patterns 222a, 222b and 222c is formed in the reflective area RFA of the blue pixel area BP adjacent to the green pixel area GP. The second photo patterns 222a, 222b and 222c are formed in the pixel areas RP, GP and BP, respectively, so that the brightness and color reproducibility in the respective reflective areas RFA of each pixel area RP, GP and BP are optimized relative to those in the respective transmissive areas TA thereof.

When a composite ratio of the color photoresist forming the red, green and blue color filters RCF, GCF and BCF in each pixel area RP, GP and BP, such as quantity of material displaying color, density of the photoresist, and so on, and the transmissivity and color reproducibility of the color photoresist is the same, the second photo patterns 222a, 222b and 222c respectively formed in each pixel area RP, GP and BP may be formed to have the same thickness.

In FIG. 4A, each pixel area RP, GP and BP of the second color filter substrate 202 of FIG. 3 is illustrated, but as discussed above, it should be understood that in the first color filter substrate 200 of FIGS. 1 and 2, the first photo patterns 220a, all having the same thickness, may be formed in each pixel area GP, GP and BP to enhance the display quality.

Referring to FIG. 4B, a third exemplary color filter substrate 204 is formed in the reflective and transmissive areas RFA and TA of each pixel area RP, GP and BP defined by the light-blocking pattern BM, and includes third photo patterns 224a, 224b and 224c, each having a different thickness than the other. The third color filter substrate 204 also includes color filters RCF, GCF and BCF, and a common electrode layer CE.

The different colors of the color photoresist materials forming the red, green and blue color filters RCF, GCF and BCF may cause a difference in the transmissivity and color reproducibility of each of the respective red, green and blue colors, such as chroma, brightness and so on, according to the particular color characteristics of the materials used in the filters. In such a case, the thickness of the third photo patterns 224a, 224b and 224c formed in each reflective area RFA of each pixel area RP, GP and BP may be controlled independently of the others so as to optimize the transmissivity and color reproducibility of respective ones of the red, green and blue color filters RCF, GCF and BCF.

For example, the thickness a of the first one 224a of the third photo patterns 224a, 224b and 224c formed in the red pixel area RP may be formed to be less than the thickness b of the second one 224b of the third photo patterns 224a, 224b and 224c formed in the green pixel area GP. A third thickness c of the third one 224c of the third photo patterns 224a, 224b and 224c formed in the blue pixel area BP may be formed to be less than the first and second thickness a and b, so as to optimize the transmissivity and color reproducibility of respective ones of the red, green and blue color filters RCF, GCF and BCF independently of the others.

Accordingly, the display quality of a display panel including the third color filter substrate 204 may be optimally enhanced. Thus, as illustrated in FIG. 4B, photo patterns 224a, 224b and 224c, each having a different thickness than the others, may be formed in each pixel area RP, GP and BP of the first color filter substrate 200 of FIG. 2 so as to optimize the brightness and color reproducibility of the display, and thereby enhance its display quality.

Referring to FIG. 5A, a fourth exemplary color filter substrate 206 includes fourth photo patterns 226a, 226b and 226c respectively formed in the reflective area RFA of each pixel area RP, GP and BP, color filters RCF, GCF and BCF, a fourth organic layer 232 respectively formed on the color filters RCF, GCF and BCF in each reflective area RFA, and a common electrode layer CE.

Each of the fourth photo patterns 226a, 226b and 226c includes a plurality of first holes 227. Since the first holes 227 are formed in each of the fourth photo patterns 226a, 226b and 226c, the thickness of the respective color filters RCF, GCF and BCF in the respective areas of the holes 227 is thicker than that of the color filters in the areas adjacent to the holes 227. For example, a volume of color photoresist material equal to the volume of the holes 227 may be injected into the holes before or during the formation of the respective color filters on the respective photo patterns 226a, 226b and 226c.

When the color photoresist material disposed in the holes 227 has the same composition, molecule size, and so on (i.e., except for the color of the material), the fourth photo patterns 226a, 226b and 226c may have the same thickness, and the first holes 227 formed in the fourth photo patterns 226a, 226b and 226c may have the same size and be of the same number. The sizes and the number of the first holes 227 in the fourth photo patterns 226a, 226b and 226c may then be controlled to easily control the respective transmissivity and color reproducibility of each of the color filters RCF, GCF and BCF in the reflective areas RFA.

The first holes 227 are formed in the fourth photo patterns 226a, 226b and 226c so that the respective transmissivity and color reproducibility of each color filter RCF, GCF and BCF may be easily controlled. In particular, the first holes 227 are formed in the fourth photo patterns 226a, 226b and 226c so that the respective transmissivity and color reproducibility of the color filters RCF, GCF and BCF formed in the reflective areas RFA may be adjusted to be respectively similar to those of the color filters RCF, GCF and BCF formed in the transmissive area TA, and thus, the overall brightness and color reproducibility of each pixel area RP, GP and BP of the display may be optimized.

Referring to FIG. 5B, a fifth color filter substrate 208 includes fifth photo patterns 228a, 228b and 228c respectively formed in each of the reflective areas RFA of each pixel area RP, GP and BP, color filters RCF, GCF and BCF, a fourth organic layer 232 formed on the color filters RCF, GCF and BCF, and a common electrode layer CE.

The fifth photo patterns 228a, 228b and 228c have a plurality of second holes 229 that are different in size and number from one another. As discussed above, it is possible that the different color photoresist materials used to form the respective red, green and blue color filters RCF, GCF and BCF may cause a difference in the respective transmissivity and color reproducibility of the filters, such as chroma, brightness and so on, according to the particular color characteristics of the material used in the color photoresist material. To compensate for this, the number and/or size of the second holes 229 formed in each photo pattern 228a, 228b and 228c may be different than those in the others.

For example, when the size of the second holes 229 is varied, the first one 228a of the fifth photo patterns 228a, 228b and 228c formed in the red pixel area RP may include second holes 229 that are larger than the holes of the second one 228b of the fifth photo patterns 228a, 228b and 228c formed in the green pixel area GP. The third one 228c of the fifth photo patterns 228a, 228b and 228c formed in the blue pixel area BP may include second holes 229 that are larger than the holes in both the first one 228a of the fifth photo pattern 228a and the second one 228b of the fifth photo patterns 228a, 228b and 228c. Alternatively or additionally, the number of the second holes 229 respectively formed in each of the fifth photo patterns 228a, 228b and 228c of each pixel area may be varied to achieve the desired control of the respective transmissibility and color reproducibility of the associated filters.

As illustrated in FIGS. 5A and 5B, when the first holes 227 and the second holes 229 are respectively formed in the fourth and fifth photo patterns 226a, 226b, 226c, 228a, 228b and 228c, the transmissivity and the color reproducibility of the respective associated color filters RCF, GCF and BCF formed in the reflective area RFA of the associated pixel may be adjusted so as to accurately control the brightness and color reproducibility of the color filters RCF, GCF and BCF and thereby enhance display quality.

According to the exemplary embodiments described herein, a photo pattern is formed in the reflective area of the pixel area, so that the brightness and color reproducibility of an associated color filter formed in the reflective area of an associated pixel may be adjusted to be similar to those of the color filter formed in the transmissive area of the pixel. For example, when a plurality of holes is formed in the photo pattern, the brightness and color reproducibility of the color filter formed in the reflective area may be accurately controlled. Accordingly, the brightness and color reproducibility in the pixel areas may be optimized so as to enhance the display quality of an LCD display panel that includes the color filter substrate.

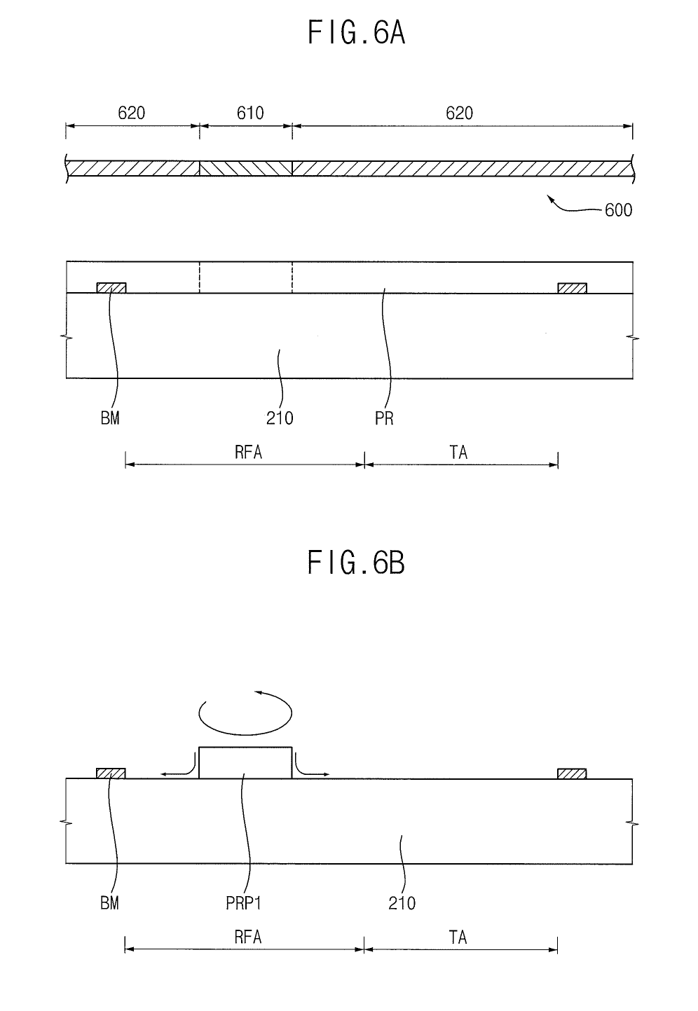

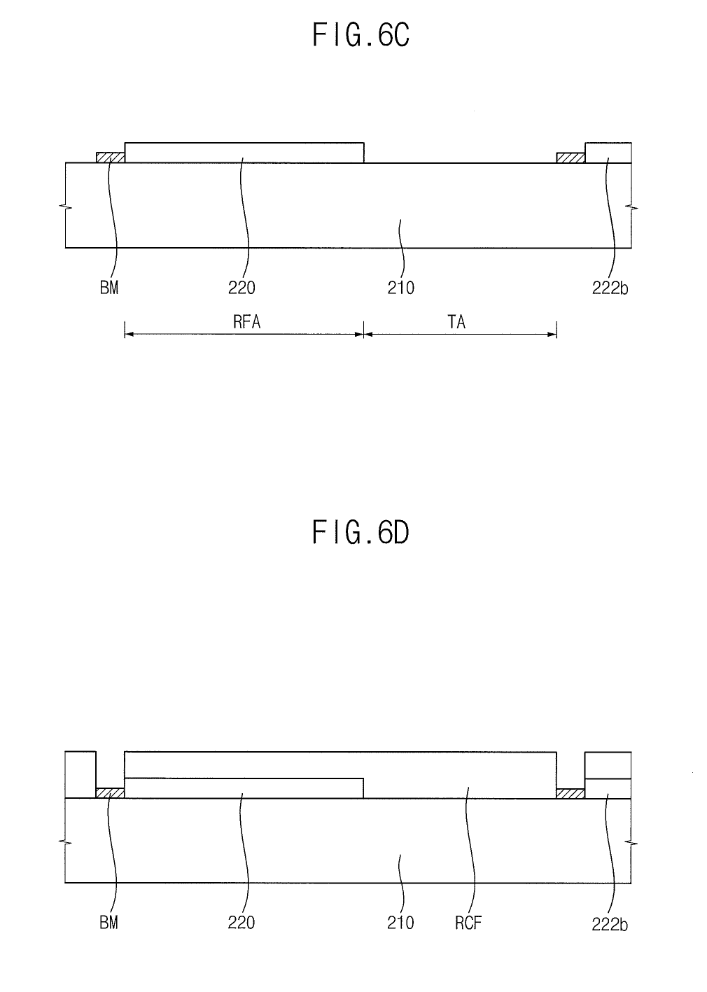

FIG. 6A to 6D are partial cross-sectional views illustrating sequential processes of an exemplary embodiment of a method for manufacturing a color filter substrate of an LCD in accordance with the present invention.

Referring to FIG. 6A, a photoresist film PR is formed on the second base substrate 210 on which the light-blocking pattern BM defining the pixel area is formed, and a first mask 600 is disposed on the second base substrate 210 on which the photoresist film PR is formed.

For example, the light-blocking pattern BM may be formed via forming a blocking layer on the second base substrate 210 and then patterning the blocking layer through a photolithography process. Alternatively, the light-blocking pattern BM may be formed via a printing process.

The photoresist film PR includes a photosensitive organic material. For example, the photosensitive organic material may include a negative type photoresist composite material, a portion of which is cured by being irradiated with light, and the portion of which that was not irradiated by the light being eliminated by a developer. Alternatively, the photosensitive organic material may include a positive type photoresist composite material, a portion of which that is irradiated by light being eliminated by a developer and the portion of which that is not irradiated by the light being cured.

As illustrated in FIG. 6A, the first mask 600 includes an opening portion 610 through which light passes, and a blocking portion 620 that blocks the passage of light. The shape of the first mask 600 may be changed in accordance with the composite material of the photoresist film PR. For example, when the photoresist film PR includes a negative type photoresist composite material, the opening portion 610 is disposed to correspond to the reflective areas RFA of the pixel area, and the blocking portion 620 is disposed to correspond to an area adjacent to the transmissive area TA and the reflective area RFA from which the photoresist film PR is to be eliminated.

Referring to FIGS. 6B and 6C, light is radiated onto the base substrate 210 through the first mask 600 so as to pattern the photoresist film PR to a first photoresist pattern PRP1. The first photoresist pattern PRP1 is thus partially formed in the reflective area RFA.

Then, the first photoresist pattern PRP1 is spread out so as to completely coat the reflective area RFA. For example, the first photoresist pattern PRP1 may be spin-coated so as to spread over the entire reflective area RFA. When the first photoresist pattern PRP1 is spin-coated, the first photoresist pattern PRP1 is spread out laterally by centrifugal force, so that the first photo pattern 220 is formed over the entire reflective area RFA. The thickness of the first photo pattern 220 and the area over which the first photo pattern 220 is formed may be varied according to the radial velocity of the spinning. The thickness of the first photo pattern 220 is formed to be less than that of the first photoresist pattern PRP1. The first photo pattern 220 is formed with a flat shape in the reflective area RFA via the coating process.

Referring to FIG. 6D, the red color filter RCF is then formed on the second base substrate 210 on which the first photo pattern 220 is formed. The red color filter RCF is formed on the first photo pattern 220 in the reflective area RFA and the second base substrate 210 in the transmissive area TA. Accordingly, the red color filter RCF formed in the reflective area RFA is thinner than the red color filter RCF formed in the transmissive area TA, and as a result, the transmissivity and color reproducibility of the red color filter RCF in the reflective area RFA may be adjusted to be similar to those of the red color filter RCF in the transmissive area TA, so that the brightness and color reproducibility in the entire pixel area is thereby optimized. As above, a red color filter RCF has been described by way of example, but it should be understood that the first photo pattern may also be formed in each of the reflective areas of the green pixel area and the blue pixel area adjacent to the pixel area in which the red color filter is formed, so that the brightness and the color reproducibility in the green and blue pixel areas are similarly optimized.

The second organic layer 230 is then formed on the red color filter RCF in the reflective area RFA, as illustrated in FIG. 2 and discussed above, to control the cell gap of the liquid crystal layer in the reflective area RFA. The common electrode layer CE is then formed over the entire second base substrate 210, including over the second organic layer 230. Alternatively, the common electrode layer CE may be formed directly on the second base substrate 210 including the red color filter substrate RCF, as illustrated in FIG. 3.

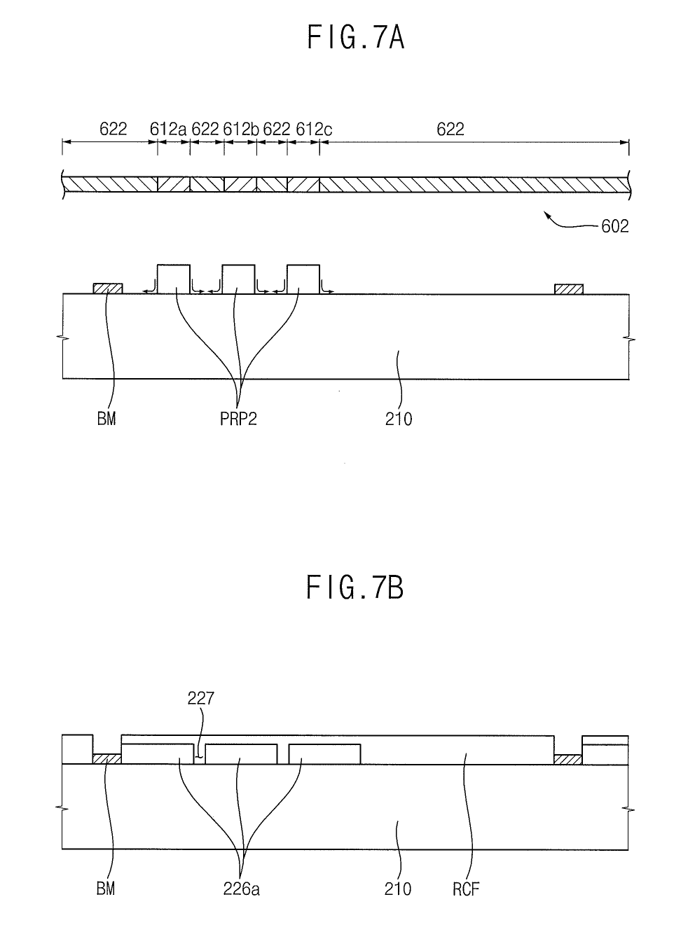

FIGS. 7A and 7B are partial cross-sectional views illustrating sequential processes of another exemplary embodiment of a method for manufacturing an LCD color filter substrate in accordance with the present invention.

Referring to FIG. 7A, a second photoresist pattern PRP2 is formed via patterning a photoresist film (not illustrated) formed on the second base substrate 210 that includes a light-blocking pattern BM defining a pixel area. The photoresist film may comprise, for example, a negative type photoresist composite material, a portion of which is cured by being irradiated with light. The second photoresist pattern PRP2 is partially formed in the reflective area RFA of the pixel area via patterning the photoresist film through a photolithography process using a second mask 602. For example, the second photoresist pattern PRP2 may be formed in a central portion of the reflective area RFA. As illustrated in FIG. 7A, the second photoresist pattern PRP2 includes a plurality of block-like patterns.

The second mask 602 includes a plurality of openings 612a, 612b and 612c and blocking portions 622. The plurality of openings 612a, 612b and 612c is disposed to correspond to the reflective area RFA, and the second photoresist pattern PRP2 including the block patterns remains in the reflective area RFA after development of the exposed photoresist. The number of the block pattern and the distance of separation between the block patterns of the second photoresist pattern PRP1 depend on the shape of the second mask 602. For example, when the second mask 602 has the shape of blocking portions separated from each other, holes are formed in the second photoresist pattern PRP2. When the second mask 602 has the shape of first, second and third opening portions 612a, 612b and 612c disposed between adjacent blocking portions 622, a second photoresist pattern PRP2 that includes three block patterns is formed.

Referring to FIG. 7B, the second photoresist pattern PRP2 is spread out so as to coat the reflective area RFA overall. For example, the second photoresist pattern PRP2 may be spin-coated, as described above. When the second photoresist pattern PRP2 is spin-coated, the second photoresist pattern PRP2 is spread out laterally by centrifugal force, so that the fourth photo pattern 226a is formed over the entire reflective area RFA with a thickness that is less than that of the second photoresist pattern PRP2.

The thickness of the fourth photo pattern 226a and the area over which the fourth photo pattern 226a is formed may be controlled in accordance with the radial velocity of the spinning. The fourth photo pattern 226a formed in the reflective area RFA is substantially flat. The fourth photo pattern 226a is formed by using the block patterns of the second photoresist pattern PRP2, so that the plurality of first holes 227 is formed in the fourth photo pattern 226a.

The red color filter RCF is then formed on the second base substrate 210 that includes the fourth photo pattern 226a in which the holes 227 are formed. In forming the red color filter RCF, the red color photoresist material is injected into the holes of the fourth photo pattern 226a. Accordingly, although a red color filter RCF having the same thickness is formed in the entire pixel area, the thickness of the red color filter RCF formed in the reflective area RFA is thinner than that of the red color filter RCF formed in the transmissive area TA, except in the respective areas of each of the holes 227.

In FIGS. 7A and 7B and the above discussion, only the pixel area in which the red color filter RCF is located is illustrated and described by way of example, but it should be understood that the fourth photo pattern may also be formed in each of the reflective areas of the green and blue pixel areas adjacent to the pixel area in which the red color filter is formed, so that the transmissivity and color reproducibility of the green and blue color filters is also optimized in the manner described above.

According to the present invention, a photo pattern is formed in the reflective area of the pixel area so that the brightness and color reproducibility of the color filter formed in that reflective area is adjusted to be similar to those of the color filter formed in the adjacent transmissive area. Accordingly, the brightness and color reproducibility of the color filter may be fully optimized to enhance the display quality.

In addition, the photoresist film, including the photosensitive organic material, is patterned by using a mask having an opening portion and a blocking portion, and the patterned photoresist film is then coated over the entire corresponding reflective area RFA, so that the thickness and the area of the photo pattern formed in the reflective area may be closely controlled. Since the photo pattern is formed by the mask with the opening and blocking portions, the number of masks needed to form a light hole in the color filter in the reflective area is decreased, thereby resulting in a corresponding decrease in manufacturing costs.

For example, when the thickness of the photo pattern and the area in which the photo pattern is formed is changed to control the brightness and the color reproducibility of the color filter formed on the photo pattern, the photo pattern may be formed on another color filter substrate using the same mask, so that a color filter substrate having a different shape may be manufactured. Accordingly, manufacturing costs are reduced, and the brightness and color reproducibility of the color filter substrate is accurately controlled, so that display quality is thereby enhanced.

As those of skill in this art will by now appreciate, many modifications, substitutions and variations may be made in and to the materials, methods and configurations of the LCD panel color filter substrates of the present invention and their methods of manufacture without departing from the spirit and scope of the invention. In light of this, the scope of the present invention should not be limited to that of the particular embodiments illustrated and described herein, as they are only by way of examples thereof, but instead, should be fully commensurate with that of the claims appended hereafter and their functional equivalents.

What is claimed is:

1. A display panel, comprising:
an array substrate, including a first base substrate having a plurality of array substrate pixel areas defined thereon, each having a reflective area, a transmissive area, a transparent electrode formed in the reflective and transmissive areas, and a reflective electrode formed on the transparent electrode in the reflective area; and,
a color filter substrate disposed opposite to the array substrate, the color filter substrate including a second base substrate having a light-blocking pattern defining a plurality of color filter substrate pixel areas thereon, each corresponding to a respective one of the array substrate pixel areas, each having reflective and transmissive areas respectively corresponding to the reflective and transmissive areas of the corresponding array substrate pixel area, and a color filter formed in the reflective area and transmissive area;
a liquid crystal layer disposed between the array substrate and the color filter substrate; and,
a photo pattern formed between the second base substrate and the color filter in the reflective area of at least some of the pixel areas of the color filter substrate.

2. The display panel of claim 1, wherein a first cell gap of the liquid crystal layer in the reflective areas of the pixel areas is smaller than a second cell gap of the liquid crystal layer in the transmissive areas of the pixel areas.

3. The display panel of claim 1, wherein each photo pattern contains a plurality of holes.

4. The display panel of claim 3, wherein selected ones of the photo patterns have a different number of the holes than the other photo patterns.

5. The display panel of claim 1, wherein selected ones of the photo patterns have a different thickness than the other photo patterns.

6. The display panel of claim 2, wherein each pixel area of the array substrate further comprises a first organic layer formed in the reflective and the transmissive areas thereof.

7. The display panel of claim 6, wherein each pixel area of the color filter substrate further comprises a second organic layer formed on the color filter in the reflective area thereof.

8. The display panel of claim 2, wherein each pixel area of the array substrate further comprises a first organic layer formed in the reflective area thereof.

9. The display panel of claim 8, wherein each pixel area of the color filter substrate further comprises a second organic layer formed in the reflective and the transmissive areas thereof.

10. The display panel of claim 2, wherein the color filter substrate further comprises a common electrode layer formed on the second base substrate.

11. A method for manufacturing a color filter substrate, the method comprising:
forming a light-blocking pattern defining a pixel area of a base substrate;
forming a photo pattern in a reflective area of the pixel area; and,
forming a color filter on the photo pattern and in a transmissive area of the pixel area.

12. The method of claim 11, wherein forming the photo pattern comprises:
forming a photoresist film on the base substrate; and,
patterning the photoresist film using a mask.

13. The method of claim 12, wherein forming the photo pattern comprises spreading the patterned photoresist film out in the reflective area.

14. The method of claim 13, wherein the photoresist film comprises a photosensitive organic material.

15. The method of claim 13, wherein the spreading of the patterned photoresist film comprises spin-coating the photoresist film.

16. The method of claim 12, wherein the patterning of the photoresist film comprises using the mask to form a plurality of holes in the photo pattern.

17. The method of claim 12, further comprising:
forming an organic layer on the base substrate; and,
patterning the organic layer so that the organic layer remains on the color filter in the reflective area.

18. The method of claim 12, further comprising forming a common electrode layer on the base substrate.
